(19) United States
(12) Patent Application Publication
(10) Pub. No.: US 2018/0265965 A1
(43) Pub. Date: Sep. 20, 2018

(54) APPARATUS AND METHOD FOR LOADING A SUBSTRATE INTO A VACUUM PROCESSING MODULE, APPARATUS AND METHOD FOR TREATMENT OF A SUBSTRATE FOR A VACUUM DEPOSITION PROCESS IN A VACUUM PROCESSING MODULE, AND SYSTEM FOR VACUUM PROCESSING OF A SUBSTRATE

(71) Applicant: Applied Materials, Inc., Santa Clara, CA (US)

(72) Inventor: John M. WHITE, Hayward, CA (US)

(21) Appl. No.: 15/761,052

(22) PCT Filed: Apr. 28, 2016
(86) PCT No.: PCT/US2016/029721

§ 371 Date: Mar. 16, 2018

Related U.S. Application Data
(60) Provisional application No. 62/252,900, filed on Nov. 9, 2015.
(60) Provisional application No. 62/246,401, filed on Oct. 26, 2015.
(60) Provisional application No. 62/246,095, filed on Oct. 25, 2015.

(51) Int. Cl. C23C 14/56; C23C 14/35; C23C 16/54; H01L 21/203; H01L 21/67

(52) U.S. Cl. CPC C23C 14/566; C23C 14/352; H01L 21/67; C23C 16/54; H01L 21/203; C23C 14/568

(57) ABSTRACT

The present disclosure provides an apparatus for loading a substrate into a vacuum processing module. The apparatus includes a Bernoulli-type holder having a surface configured to face the substrate, and a gas supply configured to direct a stream of gas between the surface and the substrate, wherein the Bernoulli-type holder is configured to provide a pressure between the substrate and the surface configured for levitation of the substrate. The substrate is a large area substrate.

### FIELD

Embodiments of the present disclosure relate to an apparatus for loading a substrate into a vacuum processing module, an apparatus configured for treatment of a substrate for a vacuum deposition process in a vacuum processing module, a system for vacuum processing of a substrate, a method for loading a substrate into a vacuum processing module, and a method for treatment of a substrate for a vacuum deposition process in a vacuum processing module. Embodiments of the present disclosure particularly relate to a pre-treatment, such as a degassing, of a substrate before a vacuum deposition process.

### BACKGROUND

Techniques for layer deposition on a substrate include, for example, sputter deposition, thermal evaporation, and chemical vapor deposition. A sputter deposition process can be used to deposit a material layer on the substrate, such as a layer of a conducting material or an insulating material. Coated materials may be used in several applications and in several technical fields. For instance, one application lies in the field of microelectronics, such as for generating semiconductor devices. Also, substrates for displays are often coated by a sputter deposition process. Further applications include insulating panels, substrates with TFT, color filters or the like.

In order to improve a quality, for example, purity and/or homogeneity, of the layers deposited on the substrates, the substrates should meet some demands. As an example, a substrate surface on which the layer is to be deposited should be free from extraneous matter, such as foreign particles. Further, an outgassing of the substrate within a vacuum chamber of the vacuum processing system should be reduced or even avoided.

In view of the above, apparatuses, systems, and methods that overcome at least some of the problems in the art are beneficial. The present disclosure particularly aims at providing apparatuses, systems, and methods for preparing a substrate that is to be loaded into a vacuum chamber of a vacuum processing system.

### SUMMARY

In light of the above, an apparatus for loading a substrate into a vacuum processing module, an apparatus configured for treatment of a substrate for a vacuum deposition process in a vacuum processing module, a system for vacuum processing of a substrate, a method for loading a substrate into a vacuum processing module, and a method for treatment of a substrate for a vacuum deposition process in a vacuum processing module are provided. Further aspects, benefits, and features of the present disclosure are apparent from the claims, the description, and the accompanying drawings.

According to an aspect of the present disclosure, an apparatus for loading a substrate into a vacuum processing module is provided. The substrate is a large area substrate. The apparatus includes a Bernoulli-type holder having a surface configured to face the substrate, and a gas supply configured to direct a stream of gas between the surface and the substrate, wherein the Bernoulli-type holder is configured to provide a pressure between the substrate and the surface for levitation of the substrate.

According to a further aspect of the present disclosure, an apparatus configured for treatment of a substrate for a vacuum deposition process in a vacuum processing module is provided. The apparatus includes a substrate holder configured to hold the substrate, a gas supply configured to direct a stream of gas along a substrate surface of the substrate, and one or more conditioning devices for adjusting at least one physical and/or chemical property of the gas directed along the substrate surface, wherein the physical and/or chemical property of the gas is selected for a treatment of the substrate.

According to a yet further aspect of the present disclosure, a system for vacuum processing of a substrate is provided. The system includes a vacuum processing module configured for a vacuum deposition process on the substrate, at least one load lock chamber connected to the processing module, and the apparatus according to the embodiments described herein.

According to another aspect of the present disclosure, a method for loading a substrate into a vacuum processing module is provided. The substrate is a large area substrate. The method includes a holding of the substrate with a Bernoulli-type holder, and a loading of the substrate onto a substrate carrier provided at a load lock chamber connected to the vacuum processing module using the Bernoulli-type holder.

According to yet another aspect of the present disclosure, a method for treatment of a substrate for a vacuum deposition process in a vacuum processing module is provided. The method includes a holding of the substrate with a substrate holder configured for loading the substrate at a load lock chamber of the vacuum processing module, a guiding of a stream of gas via a gas supply along a surface of the substrate while holding the substrate with the substrate holder, a treating of the substrate with the stream of gas while guiding the stream of gas, wherein at least one physical and/or chemical property of the gas is selected for the treating of the substrate, and a loading of the substrate onto a substrate carrier provided at the load lock chamber with the substrate holder.

According to a further aspect of the present disclosure, an apparatus for handling a substrate is provided. The apparatus includes a Bernoulli-type holder for loading the substrate onto a substrate support surface and/or for unloading the substrate from the substrate support surface.

According to a yet further aspect of the present disclosure, an apparatus for loading a substrate into a vacuum processing module is provided. The apparatus includes a Bernoulli-type holder for holding the substrate during the loading procedure.

Embodiments are also directed at apparatuses for carrying out the disclosed methods and include apparatus parts for performing each described method aspect. These method aspects may be performed by way of hardware components, a computer programmed by appropriate software, by any combination of the two or in any other manner. Furthermore, embodiments according to the disclosure are also directed at methods for operating the described apparatus. The methods for operating the described apparatus include method aspects for carrying out every function of the apparatus.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1A shows a schematic view of an apparatus for loading a substrate into a vacuum processing module according to embodiments described herein;

FIG. 1B shows a schematic view of an apparatus for loading a substrate into a vacuum processing module according to further embodiments described herein;

FIG. 1C shows a schematic view of an apparatus for loading a substrate into a vacuum processing module according to yet further embodiments described herein;

FIGS. 2A-2D show schematic views of a substrate alignment in a Bernoulli-type holder according to embodiments described herein;

FIG. 3A shows a schematic view of a Bernoulli-type holder according to embodiments described herein;

FIG. 3B shows a schematic view of a Bernoulli-type holder according to further embodiments described herein;

FIG. 4A shows a schematic view of an apparatus configured for treatment of a substrate for a vacuum deposition process in a vacuum processing module according to embodiments described herein;

FIG. 4B shows a schematic view of an apparatus configured for treatment of a substrate for a vacuum deposition process in a vacuum processing module according to further embodiments described herein;

FIGS. 5A and 5B show schematic views of an apparatus for loading a substrate into a vacuum processing module having rigid ducts according to embodiments described herein;

FIG. 6A shows a schematic top view of a system for vacuum processing of a substrate according to embodiments described herein;

FIG. 6B shows a schematic top view of a load lock chamber in an enclosure according to embodiments described herein;

FIG. 7 shows a schematic side view of a load lock chamber in an enclosure according to embodiments described herein;

FIGS. 8A-8F show schematic views of a loading procedure of a substrate into a load lock chamber of a system for vacuum processing according to embodiments described herein; and

FIG. 9 shows a flow chart of a method for loading a substrate into a vacuum processing module and/or for treatment of a substrate for a vacuum deposition process in a vacuum processing module according to embodiments described herein.

### DETAILED DESCRIPTION OF EMBODIMENTS

Reference will now be made in detail to the various embodiments of the disclosure, one or more examples of which are illustrated in the figures. Within the following description of the drawings, the same reference numbers refer to same components. Only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

The embodiments of the present disclosure direct a stream of gas across at least one surface of a substrate, such as a large area substrate, in a controlled manner. The stream of gas can be used for at least one of a treatment of the substrate, for example, before the substrate is loaded into a vacuum processing module, and a holding of the substrate in a levitating state. In particular, the stream of gas can be used for levitation of the substrate. Additionally or alternatively, the stream of gas can be used for an outgassing of the substrate and/or for a removal of foreign particles from the surface of the substrate on which a material layer is to be deposited. As an example, an outgassing of the substrate can be performed using the stream of gas before the substrate is put on a substrate carrier, such as an E-chuck. A quality, such as a purity and/or a homogeneity, of the deposited layers can be improved. Further, the stream of gas can be used to generate a reduced pressure or under pressure above the substrate such that the substrate levitates. In particular, the stream of gas can simultaneously provide two functions, namely a holding function and a treatment or pre-treatment function for the substrate.

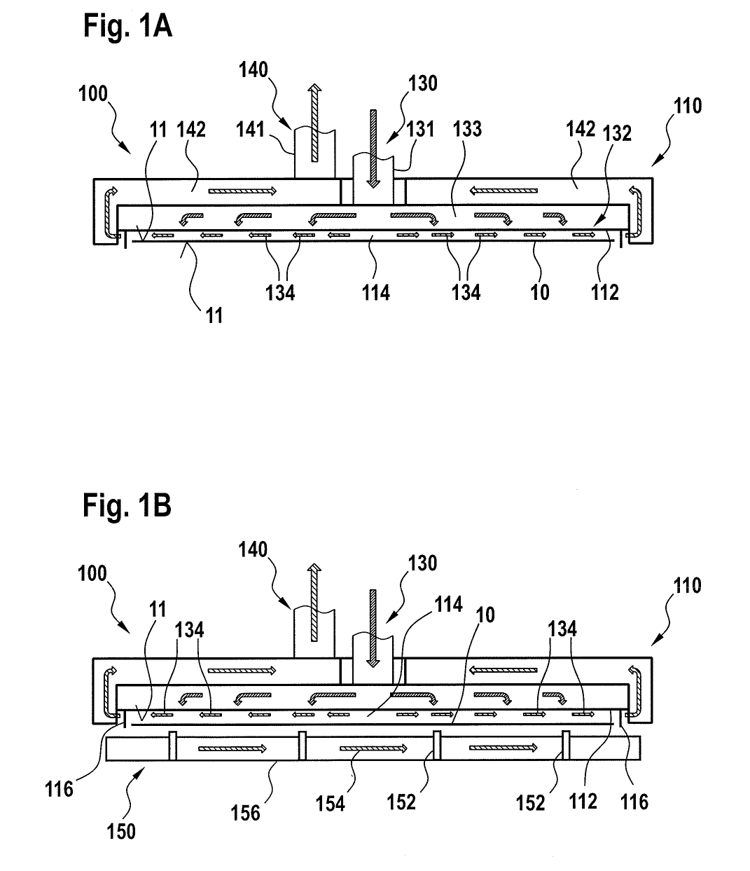

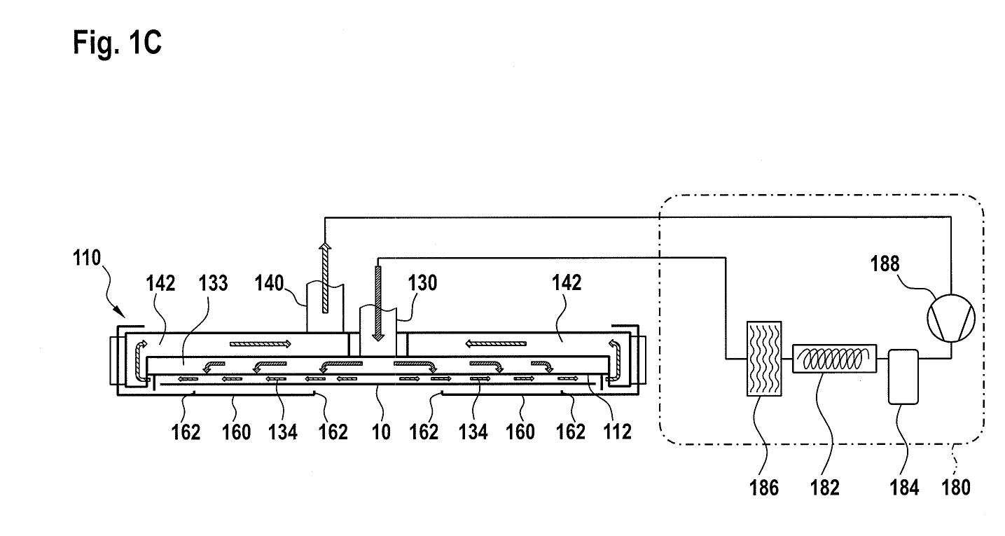

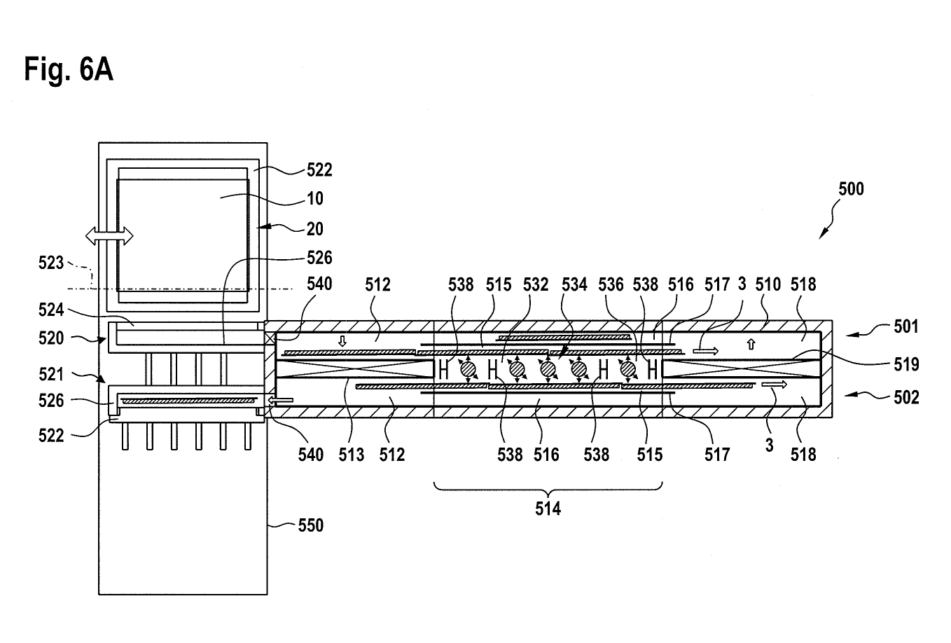

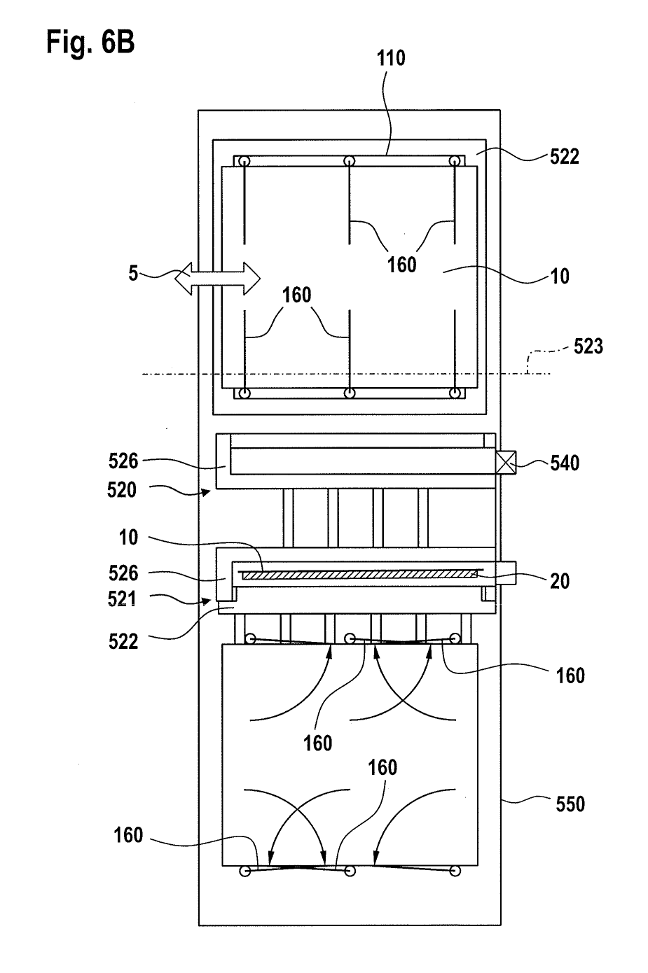

FIG. 1A shows a schematic view of an apparatus 100 for loading a substrate 10 into a vacuum processing module according to embodiments described herein. In some implementations, the apparatus 100 can be used for loading the substrate 10 into a load lock chamber of a vacuum processing system. This is further explained with respect to FIGS. 6 to 9. The substrate 10 can be a large area substrate.

The apparatus 100 includes a Bernoulli-type holder 110 having a surface 112 configured to face the substrate, and a gas supply 130 configured to direct a stream 134 of gas between the surface 112 and the substrate 10. The Bernoulli-type holder 110 is configured to provide a pressure between the substrate 10 and the surface 112 for levitation of the substrate 10.

A gap or space 114 can be provided between the surface 112 and the substrate 10 through which the stream 134 of gas flows. The gap or space 114 provided by the gas stream can be beneficial in that the position of the substrate 10 is well controlled to a small dimension and small variation in that dimension relative to the Bernoulli-type holder 110. Furthermore, the small gap protects the substrate surface from incidental environmental particle contamination and protects the substrate surface from coming into contact with the Bernoulli-type holder 110.

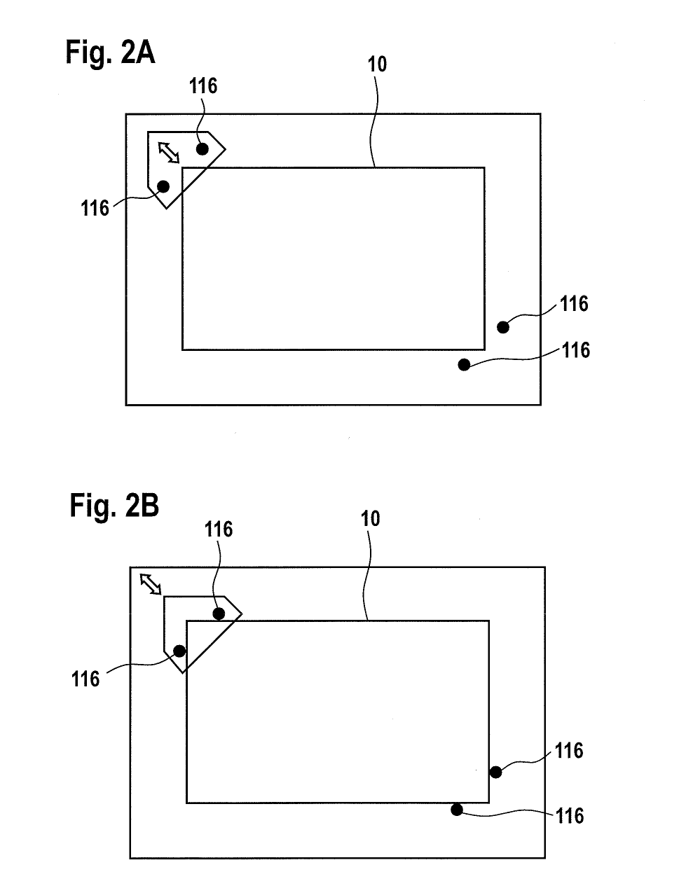

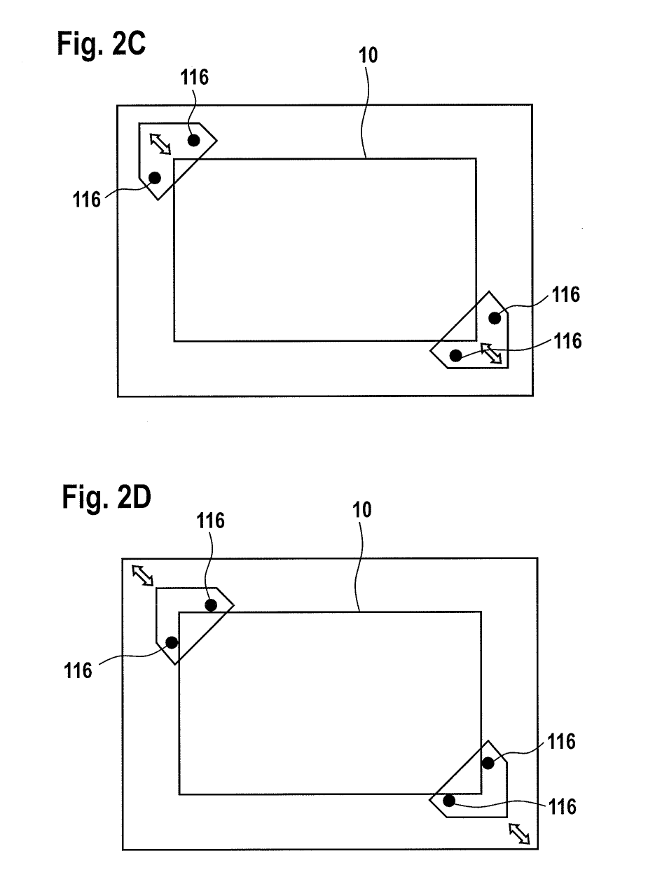

The Bernoulli-type holder 110 levitates the substrate 10 based upon the Bernoulli Effect. A pressure, such as a reduced pressure or under pressure, is provided between the substrate 10 and the surface 112 for levitation of the substrate 10 to hold the substrate 10 in a levitating or suspended state. The apparatus 100 supports the substrate 10 without making (direct) mechanical contact on the face of the substrate. In particular, the substrate 10 floats on a gas cushion, and in particular a thin gas cushion. That is, the apparatus 100 is contactless on the face of the substrate. As the substrate 10 is floating on the gas cushion, to ensure the substrate 10 does not slide off the Bernoulli-type holder 110, one or more substrate alignment devices 116 can be provided, for example pins or rollers, which protrude from the Bernoulli-type holder 110. The one or more substrate alignment devices 116 are further described with respect to FIGS. 2A and B. The stream 134 of gas provided by the apparatus 100 can optionally be used for a treatment of the substrate 10.

The terms “reduced pressure” and “under pressure” can be defined with respect to an ambient pressure in which the apparatus 100 is located, for example, in the enclosure described with respect to FIG. 6A (indicated with reference numeral “550”). In particular, the pressure, such as the reduced pressure or the under pressure, between the substrate 10 and the surface 112 is configured for levitation of the substrate 10. As an example, a difference between the pressure and the ambient pressure is sufficient to compensate for the weight force of the substrate 10.

The substrates according to embodiments described herein can have main surfaces and lateral surfaces. As an example, e.g. for a rectangular-shaped substrate, two main surfaces 11 and four lateral surfaces (or substrate edges) can be provided. The two main surfaces 11 can extend substantially parallel to each other and/or can extend between the four lateral surfaces, i.e. the edges of the substrate. An area of each of the main surfaces is larger than an area of each of the lateral surfaces. A first main surface of the two main surfaces can be configured for layer deposition thereon. The first main surface can also be referred to as “frontside” of the substrate 10. A second main surface of the two main surfaces opposite the first main surface can be referred to as the “backside” of the substrate 10. The gas supply 130 can be configured to direct the stream 134 of gas between the surface 112 of the Bernoulli-type holder 110 and a main surface, for example, the first main surface or the second main surface, of the substrate 10. In some implementations, the gas supply 130 is configured to direct the stream 134 of gas along substantially the whole substrate surface, such as the first main surface and/or the second main surface.

An area of the surface 112 of the Bernoulli-type holder 110 can be equal to, or greater than, an area of the substrate surface facing the surface 112 of the Bernoulli-type holder 110, such as the first main surface and/or the second main surface. The surface 112 of the Bernoulli-type holder 110 and the substrate surface facing the surface 112 of the Bernoulli-type holder 110 can be arranged substantially parallel to each other when the substrate 10 is held by the Bernoulli-type holder 110.

According to some embodiments, which can be combined with other embodiments described herein, the substrate 10 is a large area substrate. The large area substrate can have a size of at least 0.01 m², specifically at least 0.1 m², and more specifically at least 0.5 m². For instance, a large area substrate or carrier can be GEN 4.5, which corresponds to about 0.67 m² substrates (0.73×0.92 m), GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented.

According to some embodiments, which can be combined with other embodiments described herein, the substrate 10 is selected from the group consisting of GEN 1, GEN 2, GEN 3, GEN 3.5, GEN 4, GEN 4.5, GEN 5, GEN 6, GEN 7, GEN 7.5, GEN 8, GEN 8.5, GEN 10, GEN 11, and GEN 12. In particular, the substrate 10 can be selected from the group consisting of GEN 4.5, GEN 5, GEN 7.5, GEN 8.5, GEN 10, GEN 11, and GEN 12, or a larger generation substrates.

According to some embodiments, the gas supply 130 includes one or more first conduits 131 and/or a gas distribution plate 132. The gas distribution plate 132 can have the surface 112 configured to face the substrate 10. As an example, the gas distribution plate 132 can be provided between the one or more first conduits 131 and the large area substrate. In some implementations, the one or more first conduits 131 are configured to supply the gas into a distribution space 133 above the gas distribution plate 132. The gas distribution plate 132 can have holes or nozzles such that gas from the distribution space 133 is directed between the surface 112 and the substrate 10 to provide the stream 134 of gas. In particular, the gas distribution plate 132 can be configured to distribute the gas such that the gas flows between the substrate 10, for example, one of the main surfaces, and the surface (i.e., the surface 112) of the gas distribution plate 132.

The apparatus 100 includes a gas outlet 140. The gas outlet 140 can include one or more second conduits. As an example, the gas supplied by the gas supply 130 can flow between the surface 112 and the substrate 10, and can then be guided into one or more second conduits (indicated with reference numeral “142”) e.g. provided at one or more lateral sides of the substrate 10 and/or the gas distribution plate 132 so as to receive the gas from the gap or space 114. The gas can exit the Bernoulli-type holder 110 through an exit 141, which can be another second conduit. In some implementations, the gas exiting the Bernoulli-type holder 110 can be returned to one or more conditioning devices, as it is explained with respect to FIG. 1C.

The term “substrate” or “large area substrate” as used herein shall particularly embrace inflexible substrates, e.g., glass plates and metal plates. However, the present disclosure is not limited thereto and the term “substrate” can also embrace flexible substrates such as a web or a foil. According to some embodiments, the substrate can be made from any material suitable for material deposition. For instance, the substrate can be made from a material selected from the group consisting of glass (for instance soda-lime glass, borosilicate glass etc.), metal, polymer, ceramic, compound materials, carbon fiber materials, mica or any other material or combination of materials which can be coated by a deposition process.

FIG. 1B shows a schematic view of an apparatus for loading a substrate into a vacuum processing module according to further embodiments described herein. The apparatus of FIG. 1B is similar to the apparatus illustrated in FIG. 1A and further includes an auxiliary substrate support 150.

According to some embodiments, which can be combined with other embodiments described herein, the apparatus 100, and in particular the Bernoulli-type holder 110, includes the auxiliary substrate support 150. The auxiliary substrate support 150 can be configured to mechanically support the substrate 10. As an example, the auxiliary substrate support 150 has one or more support elements 152, such as posts or pins, e.g., lift pins or retractable pins, configured to contact and support the substrate 10.

The auxiliary substrate support 150 can be configured such that another stream 154 of gas can flow along a substrate surface of the substrate 10, for example, the first main surface and/or the second main surface. As an example, the stream 134 of gas directed between the surface 112 of the Bernoulli-type holder 110 and the substrate 10 can flow along the first main surface of the substrate 10, for example, the frontside. The other stream 154 of gas provided by the auxiliary substrate support 150 can flow along the second main surface of the substrate 10, for example, the backside. A simultaneous treatment of both main surfaces can be provided.

In some implementations, the auxiliary substrate support 150 can include a casing 156. The casing 156 can be configured such that the other stream 154 of gas can flow through the casing 156 and along the substrate surface of the substrate 10, for example, the backside.

In some implementations, the Bernoulli-type holder 110 and the auxiliary substrate support 150 can be movable with respect to each other. As an example, the Bernoulli-type holder 110 can be moved away from the auxiliary substrate support 150 for loading a substrate 10 onto the auxiliary substrate support 150, for example, the one or more support elements 152. In some implementations, a loading device such as a robot can be used to put the substrate 10 on the one or more support elements 152. The Bernoulli-type holder 110 can be moved to a position above the substrate 10 for performing a treatment, such as a preheating and/or degassing of the substrate 10. In particular, during the treatment of the substrate 10, the substrate 10 can rest on the one or more support elements 152 with the Bernoulli-type holder 110 being positioned above the substrate 10 such that the stream 134 of gas and optionally the other stream 154 of gas can be directed along the respective substrate surfaces. After the treatment process, the Bernoulli-type holder 110 can pick up the substrate 10 from the auxiliary substrate support 150 to move the substrate 10 from the auxiliary substrate support 150, for example, to a load lock chamber or to an intermediate position before loading to a load lock chamber.

FIG. 1C shows a schematic view of the apparatus 100 of FIG. 1A according to further embodiments described herein. Although not shown in FIG. 1C, the apparatus can further include the auxiliary substrate support described with respect to FIG. 1B.

According to some embodiments, which can be combined with other embodiments described herein, the apparatus 100 includes one or more conditioning devices for adjusting at least one physical and/or chemical property of the gas directed between the surface 112 and the substrate 10, such as a large area substrate. The one or more conditioning devices can also be referred to as “gas conditioning means”. The physical and/or chemical property of the gas is selected for a treatment of the substrate 10.

Specifically, the physical and/or chemical property of the gas can be selected for a pre-treatment of the substrate 10 before the substrate 10 is loaded into a vacuum processing module. For example, the pre-treatment of the substrate 10 can include at least one of heating the substrate 10, degassing the substrate 10, and providing a defined (e.g., clean, dry) environment, particularly for the surface of the substrate 10 on which a material layer is to be deposited.

The pre-treatment can be performed using the one or more conditioning devices of the Bernoulli-type holder 110. As an example, the gas exiting the Bernoulli-type holder 110 through the gas outlet 140 can be returned to the one or more conditioning devices. As indicated by reference numeral 180, the one or more conditioning devices can be located remotely. The remote area can be somewhere in the factory but does not necessarily need to be next to or close to the Bernoulli-type holder 110 or a system for vacuum processing.

According to some embodiments, which can be combined with other embodiments described herein, the one or more conditioning devices can be selected from the group including a heater 182 configured for heating the gas, a dryer 184 configured for drying the gas, a filter 186 configured for filtering the gas, a compressor 188 for circulating the gas, and any combination thereof.

In some embodiments, the Bernoulli-type holder 110 is provided with a heating function, for example, using the heater 182. In another embodiment, a heater (not shown) may be also incorporated inside the Bernoulli-type holder 110, e.g., either instead of or in addition to the heater 182. Accordingly, the Bernoulli-type holder 110 can also be referred to as “Bernoulli heater”. The dryer 184 can be configured to remove humidity from the gas that is to be supplied to the Bernoulli-type holder 110. The filter 186 can be an ultra-filter, e.g., a filter utilizing a semi-permeable membrane, or a high-efficiency particulate arresting (HEPA) filter. In another embodiment, an ultra-filter (not shown) may be incorporated in the Bernoulli-type holder 110, e.g., either instead of or in addition to the filter 186. The compressor 188 can be configured for circulating the gas within the apparatus 100, for example, from the gas outlet 140 to the gas supply 130, further through the gap or space 114, and finally to the gas outlet 140 again. According to some embodiments, which can be combined with other embodiments described herein, the gas circulating in the apparatus 100 can be nitrogen.

At least one of dry, hot, and filtered gas, such as nitrogen, can be provided for the Bernoulli-type holder 110 and the substrate 10, such as the (main) surface to be processed, contactlessly held in the Bernoulli-type holder 110. The surface of the substrate 10 can be heated and/or cleaned. The environment provided by the gas having the adjusted physical and/or chemical property can be at least one of hot, dry, clean, and chemically-inert, to allow for a degassing of the substrate 10 or substrate surface. For example, moisture adhering to the surface of the substrate 10 can be reduced.

According to some embodiments, which can be combined with other embodiments described herein, the Bernoulli-type holder 110 further includes one or more safety retainers 160 configured to be positioned below the substrate 10, such as a large area substrate. A gap can be provided between the substrate 10 and the one or more safety retainers 160, in particular when the substrate 10 is in the levitating or suspended state. The one or more safety retainers 160 can also be referred to as “fail-safe substrate retainers”. The one or more safety retainers 160 can retain the substrate 10 in the event of a sudden unexpected loss of gas flow through the Bernoulli-type holder 110. The one or more safety retainers 160 can have contact elements 162 in the case that an emergency contact between the substrate 10 and the one or more safety retainers 160 occurs.

In some implementations, the one or more safety retainers 160 are configured to be rotatable with respect to the substrate 10. As an example, the one or more safety retainers 160 can be rotatable from a first position to a second position. In the first position, the one or more safety retainers 160 can be positioned directly below the substrate 10 to hold or catch the substrate 10, e.g., in case of a malfunction of the Bernoulli-type holder 110. In the second position, the one or more safety retainers 160 can be positioned away from the substrate 10 such that the substrate 10 can be released or taken away from the Bernoulli-type holder 110. Specifically, the one or more safety retainers 160 can be rotatable so that the safety retainers may quickly move out of the way when necessary, e.g., just prior to a pick or place action with the substrate 10. In some embodiments, an angle between the first position and the second position can be about 90°. In other words, the one or more safety retainers 160 can be rotated by 90° from the first position to the second position or from the second position to the first position. The rotation can be a rotation in a plane that is substantially horizontally oriented.

The Bernoulli-type holder 110 provides a device for pre-heating and/or degassing of the substrate 10 (e.g., of adsorbed water) before the substrate 10 enters a vacuum system. Further, a controlled clean dry chemically-inert environment for the substrate surface on which a material layer is to be deposited can be provided, while the substrate 10 is degassing and waiting to be processed. Moreover, the Bernoulli-type holder 110 provides a device for transporting and picking/placing the substrate 10 directly from/upon a carrier (e.g., an E-chuck) or support surface without any additional devices or locations of support (such as lift pins) to be arrayed on the backside of the substrate 10. The Bernoulli-type holder 110 can accomplish the functions without adding considerable footprint to a vacuum processing system.

As illustrated in FIGS. 1A, 1B and 1C, at least four substrate alignment devices can be provided. In particular, one or more substrate alignment devices can be provided at, for example adjacent to, each one of the four lateral sides of the substrate 10. The one or more substrate alignment devices at each lateral side can be positioned off-center with respect to the respective lateral side. As an example, the one or more substrate alignment devices at each lateral side can be positioned at a corner portion of the respective lateral side. A restricted movement or loose alignment of the substrate 10 can be facilitated.

FIGS. 2A-D show schematic views of a substrate alignment in a Bernoulli-type holder according to embodiments described herein.

According to some embodiments, the apparatus includes the one or more substrate alignment devices 116, such as pins or rollers. In particular, the Bernoulli-type holder can include the one or more substrate alignment devices 116 to align the substrate 10 before the substrate 10 is put on a substrate support, such as the substrate carrier, which can be an E-Chuck. In some implementations, the one or more substrate alignment devices 116 include at least one of one or more moveable substrate alignment devices and one or more fixed substrate alignment devices. The one or more substrate alignment devices 116 provide for an improved alignment of the substrate 10 on the substrate support, such as the substrate carrier, before the substrate carrier having the substrate 10 positioned thereon is loaded into the load lock chamber or the vacuum processing system.

As the substrate 10 is floating on the gas cushion, to ensure the substrate 10 does not slide off the Bernoulli-type holder, there are the one or more substrate alignment devices 116, for example pins or rollers, provided which can protrude from the face of the Bernoulli-type holder which surrounds the substrate 10. At least one substrate alignment device can be provided for each of the four (lateral) edges of the substrate 10, such that the in-plane movement of the substrate 10 is restricted to an area which is slightly larger than the areal dimensions of the substrate 10, e.g., less than ±20 mm, preferably less than ±8 mm, and more preferably less than ±3 mm, e.g., in both dimensions (X and Y in a horizontal plane).

FIGS. 2A and C show the one or more substrate alignment devices 116 in an open position. FIGS. 2B and D show the one or more substrate alignment devices 116 in a closed or aligned position. According to some embodiments, at least some substrate alignment devices of the one or more substrate alignment devices 116 can be movable between the open position and the closed position, for example, in a plane substantially parallel to the main surface(s) of the substrate 10. Optionally, at least some substrate alignment devices of the one or more substrate alignment devices 116 can be fixed in position. FIGS. 2A and B illustrate an embodiment having one or more moveable substrate alignment devices (at the left upper corner of the substrate 10) and one or more fixed substrate alignment devices (at the right lower corner of the substrate 10). FIGS. 2C and D illustrate an embodiment with opposing moveable substrate alignment devices, e.g., at the left upper corner and the right lower corner of the substrate 10. The moveable alignment device can include an actuatable clamping plate having the pins or rollers fixed thereto. In the open position, the one or more substrate alignment devices 116 can be spaced apart from the substrate 10 such that the one or more substrate alignment devices 116 do not contact the substrate 10. In the closed position, the one or more substrate alignment devices 116 can be configured to contact the substrate 10, for example, the lateral surface(s) of the substrate 10.

With respect to FIGS. 2C and 2D and the opposing movable substrate alignment devices, a benefit of this design is that the design avoids having to move the whole Bernoulli-type holder slightly away from the substrate 10 when releasing the substrate 10. The moveable substrate alignment devices, which can be moveable pins, can be moved away before the Bernoulli-type holder is lifted. In particular, if the whole Bernoulli-type holder is not moved, the fixed set of pins would drag against the edge of the substrate as the Bernoulli-type holder is lifted up. The motion can be easily put into the pins and the whole Bernoulli-type holder does not need to be moved, e.g., diagonally.

In some implementations, the substrate 10 can be picked up, for example, from the auxiliary substrate support with the one or more substrate alignment devices 116 being in the open position. The substrate 10 can be held by the Bernoulli-type holder in the levitating state, i.e., without mechanical contact. Before the substrate 10 is placed on the substrate support, such as an E-Chuck, the one or more substrate alignment devices 116 can be moved into the closed position such that the substrate 10 is aligned with respect to the substrate support. As an example, the one or more substrate alignment devices 116 can be moved from the open position to the closed position after the substrate 10 has been moved to a load lock chamber and before the substrate 10 is put on the substrate support provided by, or at, the load lock chamber.

In some embodiments, at least some substrate alignment devices of the one or more substrate alignment devices 116, such as pins or rollers, may be mounted in such a way that they are able to move from the open position or condition which defines an area which may be larger than the substrate by, for example, 10 to 15 mm on each side, to the closed position or condition which can align the substrate 10 by making contact with the edge of the substrate 10 and pushing the substrate 10 toward a set of opposing substrate alignment devices, which also may be similarly moveable or may be mounted in a fixed position. Since the substrate 10 is floating on a gas cushion there is very little resistance to the movement induced by the moveable substrate alignment devices. The moveable substrate alignment devices may be moved to a predetermined stop position which would leave a small clearance, e.g., less than 5 mm and preferably less than 2 mm, but would not clamp the substrate 10 between the opposing set of moveable or fixed substrate alignment devices and the fixed substrate alignment devices. Alternatively, the moveable substrate alignment devices may be moved forward until the substrate 10 is very lightly clamped between the opposing sets of substrate alignment devices without leaving clearance. After releasing the pressure condition levitating the substrate 10 and transferring the substrate 10 to the new position, the moveable clamping devices may be opened and/or the entire assembly including the Bernoulli-type holder with the substrate alignment devices may be moved slightly so as to no longer make contact with the edge of the substrate 10. The assembly may then be safely moved vertically away from the substrate 10.

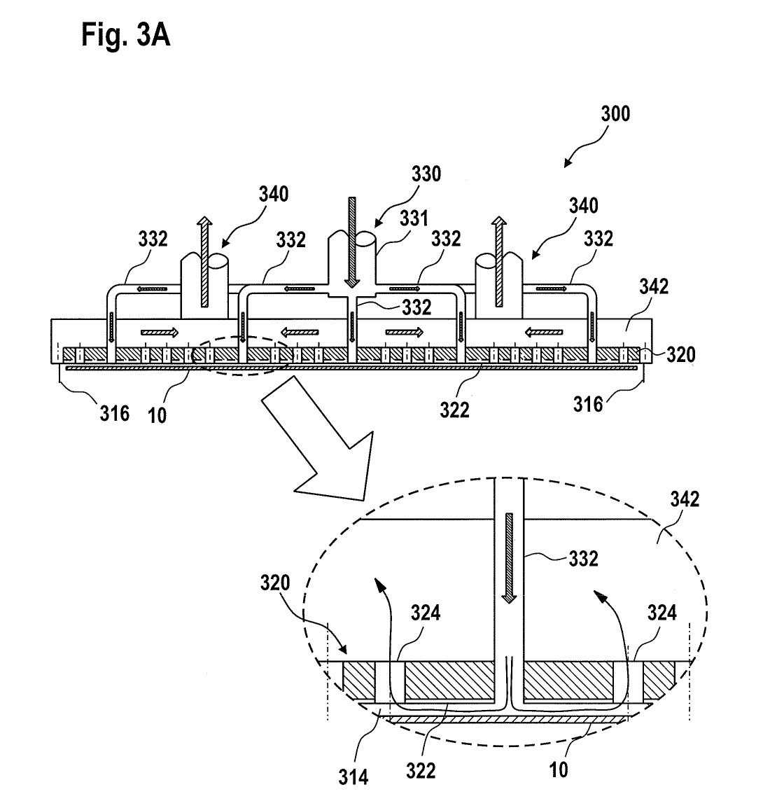

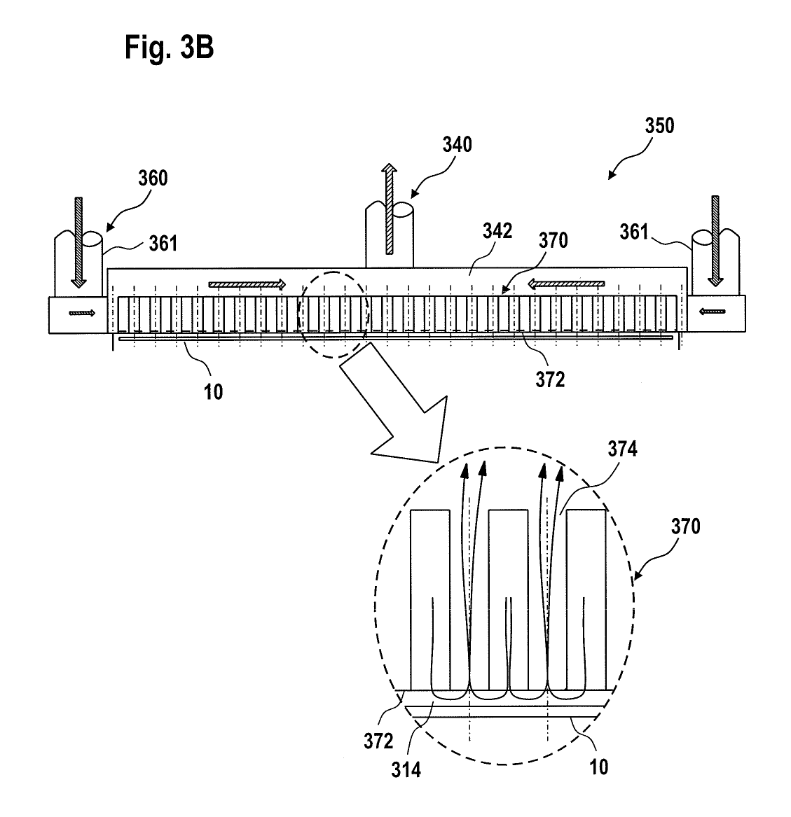

FIG. 3A shows a schematic view of a Bernoulli-type holder 300 according to embodiments described herein. The Bernoulli-type holder 300 uses a “local” Bernoulli effect at a number of discrete distributed positions to hold the substrate 10 in the levitating state. The Bernoulli-type holder 300 can be configured to supply heated gas, such as hot nitrogen, to the substrate 10 for levitation and pre-treatment (e.g., preheating) of the substrate 10. As an example, the Bernoulli-type holder 300 can include a heater (not shown) for heating the gas. The gas can be hot, filtered and dry nitrogen.

The Bernoulli-type holder 300 includes a gas supply 330 configured to direct a stream of gas between a surface 322 of the Bernoulli-type holder 300 and the substrate 10 for levitation of the substrate 10. The gas supply 330 includes a main supply pipe 331 and a plurality of distribution pipes 332 connected to the main supply pipe 331. The plurality of distribution pipes 332 are configured to direct the stream of gas between the surface 322 and the substrate 10.

The Bernoulli-type holder 300 includes an aperture plate 320. The aperture plate 320 provides the surface 322 of the Bernoulli-type holder 300 that faces the substrate 10. The aperture plate 320 includes a plurality of return apertures or openings 324. For example, the plurality of return apertures or openings 324 can be distributed, and particularly uniformly distributed, along the surface 322. The plurality of distribution pipes 332 can extend through the aperture plate 320 to supply the gas into the gap or space 314 between the surface 322 and the substrate 10. Gas supplied by the gas supply 330 can flow into the gap or space 314 via the plurality of distribution pipes 332 and can then flow from the gap or space 314 through the plurality of return apertures or openings 324 to a gas outlet 340, for example, via one or more outlet conduits 342 provided at a backside of the aperture plate 320, as it is shown in the enlarged section of FIG. 3A. The plurality of return apertures or openings 324 through which the gas can exit the gap or space 314 allows for creating a local Bernoulli effect for levitation of the substrate 10.

In some implementations, the Bernoulli-type holder 300 includes one or more retaining pins 316 for retaining the substrate 10. The one or more retaining pins 316 can be configured similarly or identically to the one or more substrate alignment devices described with respect to, for example, FIGS. 2A and B.

FIG. 3B shows a schematic view of a Bernoulli-type holder 350 according to further embodiments described herein. The Bernoulli-type holder 350 of FIG. 3B is similar to the Bernoulli-type holder 300 described with respect to FIG. 3A, and a description of similar or identical elements is not repeated. In particular, also the Bernoulli-type holder 350 uses a “local” Bernoulli effect at a number of discrete distributed positions to hold the substrate 10 in the levitating state.

The Bernoulli-type holder 350 can have a gas supply 360 including one or more gas inlets 361 provided at lateral sides of the Bernoulli-type holder 350. The Bernoulli-type holder 350 includes a gas distribution arrangement 370 having the surface 372 that faces the substrate 10 such that the stream of gas can be directed between the surface 372 and the substrate 10 for levitation of the substrate 10. The gas distribution arrangement 370 is connected to the one or more gas inlets 361 and is configured for directing the gas into the gap or space 314 between the surface 372 and the substrate 10. As an example, the gas distribution arrangement 370 can have one or more conduits and/or openings to direct the gas into the gap or space 314. In some implementations, the gas distribution arrangement 370 is configured for uniformly distributing the gas across the surface 372.

In some implementations, the gas distribution arrangement 370 has a plurality of return apertures or openings 374. The plurality of return apertures or openings 374 can be distributed, and specifically uniformly distributed, along the surface 372. Gas supplied by the gas supply 360 can flow into the gap or space 314 and can then flow from the gap or space 314 through the plurality of return apertures or openings 374 to the gas outlet 340, for example, via one or more outlet conduits 342 provided at a backside of the gas distribution arrangement 370, as it is shown in the enlarged section of FIG. 3B. The plurality of return apertures or openings 374 through which the gas can exit the gap or space 314 allows for creating a uniformly-distributed local Bernoulli effect for levitation of the substrate 10.

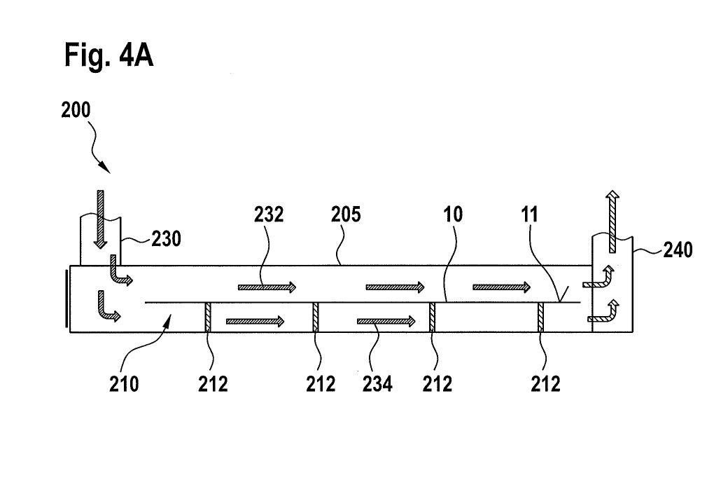

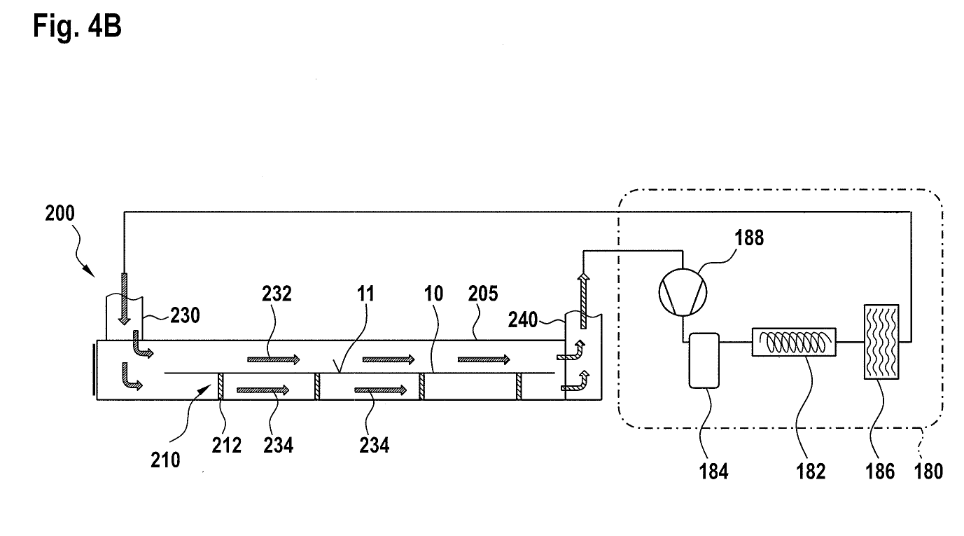

FIG. 4A shows a schematic view of an apparatus 200 configured for treatment of a substrate 10 for a vacuum deposition process in a vacuum processing module according to embodiments described herein. According to some embodiments, the substrate 10 is a large area substrate.

The apparatus 200 includes a substrate holder 210 configured to hold the substrate 10, a gas supply 230 configured to direct a stream of gas along at least one substrate surface of the substrate 10, and one or more conditioning devices (not shown) for adjusting at least one physical and/or chemical property of the gas directed along the substrate surface. The physical property and/or chemical of the gas is selected for a treatment of the substrate 10. In some implementations, the gas supply 230 is configured to direct the stream of gas along substantially the whole substrate surface, such as the first main surface and/or the second main surface.

According to some embodiments, the at least one physical and/or chemical property of the gas can be selected from the group including a temperature, pressure, flow velocity, flow direction, humidity, gas composition, and any combination thereof. As an example, physical and/or chemical properties of the gas can be selected for a pre-treatment of the substrate 10 before a vacuum deposition process is conducted on the substrate 10 and/or before the substrate 10 is put on a substrate carrier, such as an E-Chuck. The treatment can include an outgassing of the substrate 10 or substrate surface and/or a cleaning of the substrate 10 or substrate surface. In particular, the apparatus 200 can provide a controlled environment for the substrate 10 such that the treatment, for example, the outgassing or cleaning, can be efficiently conducted.

The at least one substrate surface can include, for example, a substrate surface on which a material layer is to be deposited (e.g., the first main surface or frontside) and/or a substrate surface on which no material layer is to be deposited (e.g., the second main surface or backside). A stream of gas flowing along the first main surface is indicated with reference numeral 232, and a stream of gas flowing along the second main surface is indicated with arrow 234.

According to some embodiments, the apparatus 200 includes a holder enclosure 205 configured for accommodating the substrate holder 210 and the substrate 10. The gas supply 230 and a gas outlet 240 can be connected to the holder enclosure 205, for example, at opposite (e.g., lateral) sides of the holder enclosure 205. Gas can enter the holder enclosure 205 through the gas supply 230, can flow through the holder enclosure 205 along the at least one substrate surface, and can exit the holder enclosure 205 through the gas outlet 240. The holder enclosure 205 can provide a substantially enclosed environment for the substrate 10 to provide for improved treatment conditions. In some implementations, the holder enclosure 205 has at least one opening configured such that the substrate 10 can be inserted into, and removed from, the holder enclosure 205 through the opening. According to some embodiments, the opening can be closed at least during the treatment of the substrate 10, for example, using a cover, such as a lid.

In some implementations, the substrate holder 210 includes one or more posts or pins 212 on which the substrate 10 can rest. The one or more posts or pins 212 can extend substantially vertically. As an example, the one or more posts or pins 212 can be configured to support the backside (e.g., the second main surface or backside) of the substrate 10. Further, the one or more posts or pins 212 can be configured such that a stream of gas can be directed along the substrate surface (e.g., the second main surface or backside) supported by the one or more posts or pins 212, as it is indicated with arrow 234. Moreover, the one or more posts or pins 212 can be configured such that a robot can pick up the substrate 10 by contacting the substrate surface which also contacts the one or more posts or pins 212. In some implementations, the one or more posts or pins 212 can be retractable. The one or more posts or pins 212 can retract when the robot has engaged the substrate surface to allow for a removal of the substrate 10 from the holder enclosure 205, for example, through the opening in the holder enclosure 205.

According to some embodiments, which can be combined with other embodiments described herein, the gas supply 230 is configured for supplying the stream of gas into the holder enclosure 205, directing the stream of gas along the substrate surface and returning the gas along with entrained particles and gasses desorbed from the substrate 10 in a continuously or quasi-continuously recirculating flow path.

In some implementations, the substrate holder 210 is a Bernoulli-type holder according to the embodiments described herein. Particularly, the Bernoulli-type holder can have a surface (the surface 112 of FIG. 1A) configured to face the substrate 10. The gas supply 230 can be configured to direct the stream of gas between the surface and the substrate 10 for levitation of the substrate 10.

The one or more conditioning devices can be selected from the group consisting of a heater configured for heating the gas, a dryer configured for drying the gas, a filter for filtering the gas, a compressor, and any combination thereof. The one or more conditioning devices are further explained with respect to FIGS. 1C and 4B.

FIG. 4B shows a schematic view of the apparatus 200 of FIG. 4A according to further embodiments described herein.

The apparatus 200 includes the one or more conditioning devices selected from the group consisting of a heater 182 configured for heating the gas, a dryer 184 configured for drying the gas, a filter 186 configured for filtering the gas, a compressor 188 for circulating the gas, and any combination thereof. The one or more conditioning devices can be configured similarly or identically to the one or more conditioning devices described with respect to FIG. 1C, and the description given with respect to FIG. IC applies to the apparatus 200 of FIG. 4B.

In particular, at least one of dry, hot, and filtered gas, such as nitrogen, can be provided for the substrate holder 210 and the substrate 10. One or more surfaces of the substrate 10, such as the first main surface and the second main surface, can be heated and/or cleaned. In particular, the environment provided by the gas within the holder enclosure 205 having the adjusted physical and/or chemical property can be at least one of hot, dry, clean, and chemically-inert, to allow for a degassing of the substrate 10 or substrate surface. For example, moisture adhering to the surface of the substrate 10 can be reduced.

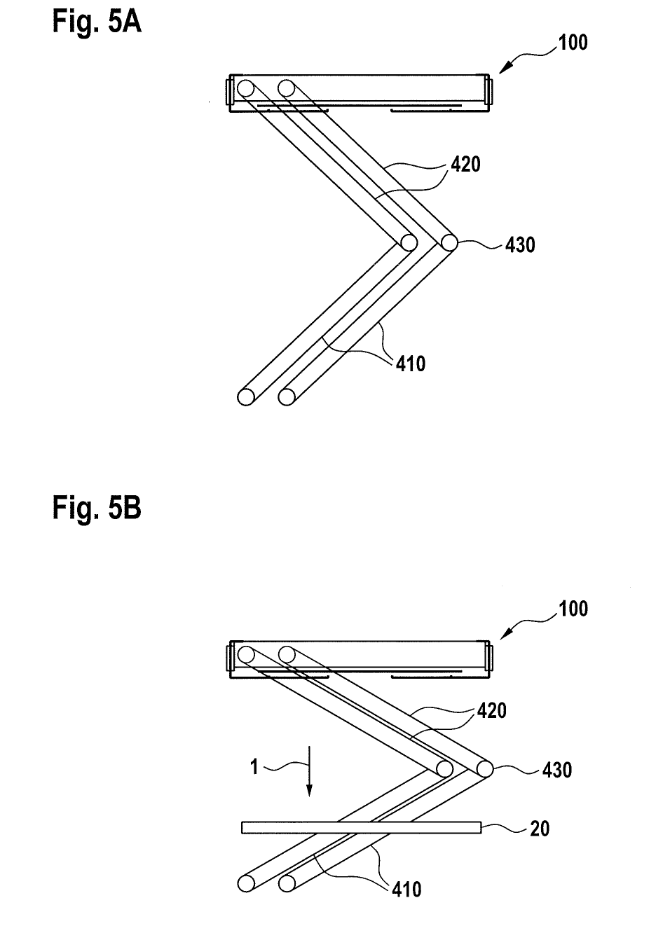

FIGS. 5A and B show schematic views of the apparatus 100 for loading a large area substrate in a vacuum processing module having rigid ducts according to embodiments described herein. The apparatus 100 can be configured as described with respect to FIGS. 1A-C.

The gas supply of the apparatus 100 includes two or more rigid ducts. At least a first rigid duct 410 and a second rigid duct 420 of the two or more rigid ducts are connected to each other with a rotary joint 430 to allow for fluid communication between the first rigid duct 410 and the second rigid duct 420. As an example, the two or more rigid ducts can connect the Bernoulli-type holder 110 and the one or more conditioning devices such that the gas can flow between the Bernoulli-type holder 110 and the one or more conditioning devices. Providing the two or more rigid ducts (as opposed to flexible ducts) reduces particle generation, for example, within a clean room environment in which the apparatus 100 is located.

According to some embodiments, the apparatus 100, and particularly the Bernoulli-type holder 110, can be configured to move substantially vertically and/or substantially horizontally. As an example, the Bernoulli-type holder 110 can move downwards as indicated with arrow 1 to put the substrate 10 on a substrate support 20 and/or can move upwards for picking up a substrate 10 from the substrate support 20. The rotary joint 430 allows for a relative movement of the first rigid duct 410 with respect to the second rigid duct 420 such that the Bernoulli-type holder 110 can move, for example, substantially vertically and/or substantially horizontally.

The substrates of the present disclosure can be supported on a substrate support 20, e.g., during a vacuum deposition process and/or a loading of the substrate into a vacuum processing module. It is noted that the terms “substrate support”, “carrier” and “substrate carrier” can be used synonymously.

In some implementations, the substrate support 20 includes, or is, an electrostatic chuck (E-chuck). The E-chuck can have a supporting surface for supporting the substrate 10 thereon. In one embodiment, the E-chuck includes a dielectric body having electrodes embedded therein. The dielectric body can be fabricated from a dielectric material, preferably a high thermal conductivity dielectric material such as pyrolytic boron nitride, aluminum nitride, silicon nitride, alumina or an equivalent material. In some implementations, the dielectric body can be made of a polymer material such as polyimide. The electrodes may be coupled to a power source, which provides power to the electrodes to control a chucking force. The chucking force is an electrostatic force acting on the substrate 10 to fix the substrate 10 on the supporting surface.

Unlike open-frame carriers, an E-chuck supports substantially a whole surface of the substrate 10, such as the second main surface or backside. A bending of the substrate 10 can be avoided, since substantially the whole surface is attached to the defined supporting surface of the E-chuck. The substrate 10 can be supported more stably and a process quality can be improved.

In some implementations, the substrate support 20 includes, or is, an electrodynamic chuck or Gecko chuck (G-chuck). The G-chuck can have a supporting surface for supporting the substrate thereon. The chucking force is an electrodynamic force acting on the substrate 10 to fix the substrate 10 on the supporting surface.

FIG. 6A shows a schematic top view of a system 500 for vacuum processing of a substrate according to embodiments described herein.

The system 500 includes a vacuum processing module configured for a vacuum deposition process on the substrate, at least one load lock chamber connected to the processing module, and the apparatus according to the embodiments described herein. The apparatus can be configured as described with respect to any one of FIGS. 1 to 5. The system 500 exemplarily shows a first load lock chamber 520 and a second load lock chamber 521. The at least one load lock chamber can have a chamber housing 526 and a door 522, wherein the door 522 is configured to close an opening 524 in the chamber housing 526. The opening 524 in the chamber housing 526 can be configured such that the substrate 10 can be loaded into, and unloaded from, the chamber housing 526 through the opening 524.

According to some embodiments, the door 522 can be configured to support the substrate 10 or substrate support 20. The door 522 can be rotatable around a rotational axis 523, which can be a substantially horizontal rotational axis. As an example, the door 522 can be rotatable between a first or open position and a second or closed position. In the first or open position, the door 522 can be oriented substantially horizontally such that the substrate 10 or substrate support 20 can be put on the door 522, for example, a support surface provided by the door 522. The door 522 having the substrate 10 and/or substrate support 20 positioned thereon can then rotate from the first or open position to the second or closed position to load the substrate 10 or substrate support 20 into the chamber housing 526. The second or closed position can be a substantially vertical position of the door 522. The substrate 10 and/or the substrate support 20 can be moved from a horizontal orientation to a vertical orientation and vice versa using the rotation of the door 522.

In some implementations, the system 500 includes an enclosure 550 surrounding at least the load lock chamber, such as the first load lock chamber 520 and the second load lock chamber 521. In the example shown in FIG. 6A, the first load lock chamber 520 having the chamber housing 526 and the door 522 in an open (horizontal) position would be under atmospheric pressure. The second load lock chamber 521 having the door 522 in a closed (vertical) position at the chamber housing 526 would be under vacuum.

FIG. 6A shows the load lock chambers positioned in the enclosure 550 providing a predefined atmospheric condition for the substrates outside of the vacuum within the vacuum processing module of the vacuum processing system, which can be an in-line processing system. The enclosure 550 can be provided as a clean room environment. Cleanrooms maintain particle-free air through the use of filters employing, for example, laminar or turbulent air flow principles. Further, the enclosure 550 can provide an environment having a defined temperature. Within the enclosure 550, the temperature can be provided with high stability.

According to some embodiments, which can be combined with other embodiments described herein, the enclosure 550 can be a sheet metal enclosure or another lightweight enclosure, in which a dry air purge is provided for the area surrounding the load lock chambers. The enclosure 550 does not need to withstand pressure differences between vacuum and atmosphere. In some implementations, the enclosure 550 can have a door through which personnel can enter the enclosure 550. As an example, the door can be configured as an airlock. The enclosure 550 can have a gas inlet (not shown) for dry air. The enclosure 550 may use ultra-filtered, dry-air-purge, e.g. for the front end loading and unloading of the substrates on the substrate support. This protects the load lock chambers from contamination with moisture, provides a clean environment for the substrate with exposed surfaces to be processed, and/or preserves human safety from the moving substrates and mechanisms and any heat sources.

In some implementations, the enclosure 550 can have a dimension which is at maximum three times the corresponding dimension of the one or more load lock chambers provided therein. This limits the volume with specific atmospheric conditions, such as a dry air purge. Further, this limits the footprint.

The vacuum processing module has a vacuum chamber 510. The vacuum chamber 510 is connected to the at least one load lock chamber, for example, using gate valves 540. The substrates can be loaded from the load lock chamber into the vacuum chamber 510 through the gate valves 540. The substrates can be unloaded from the vacuum chamber 510 into the load lock chamber through the gate valves 540, and particularly through the same gate valve through which a respective substrate has been loaded into the vacuum chamber 510.

According to some embodiments, one single vacuum chamber, such as the vacuum chamber 510, for deposition of layers therein can be provided. A configuration with one single vacuum chamber having a plurality of areas, such as a first area 512, a second area 518 and a deposition area 515 between the first area 512 and the second area 518, can be beneficial in an in-line processing system, for example, for dynamic deposition. The one single vacuum chamber with different areas does not include devices for vacuum tight sealing of one area (e.g., the first area 512) of the vacuum chamber 510 with respect to another area (e.g., the deposition area 515) of the vacuum chamber 510. In some implementations, further chambers can be provided adjacent to the vacuum chamber 510, such as the load lock chamber(s) or further processing chambers. The vacuum chamber 510 can be separated from adjacent chambers by valves, such as the gate valves 540, which may have a valve housing and a valve unit.

In some embodiments, an atmosphere in the vacuum chamber 510 can be individually controlled by generating a technical vacuum, for example with vacuum pumps connected to the vacuum chamber 510, and/or by inserting process gases in the deposition area(s) in the vacuum chamber 510. According to some embodiments, process gases can include inert gases such as argon and/or reactive gases such as oxygen, nitrogen, hydrogen and ammonia (NH3), Ozone (O3), or the like.

The system 500 has one or more sputter deposition sources, such as one or more bi-directional sputter deposition sources, in the vacuum chamber 510. In some implementations, the one or more sputter deposition sources can be connected to an AC power supply (not shown) such that the one or more sputter deposition sources can be biased in an alternating manner. However, the present disclosure is not limited thereto and the one or more sputter deposition sources can be configured for DC sputtering or a combination of AC and DC sputtering.

In some implementations, the system 500 includes one or more transportation paths at least partially extending through the vacuum chamber 510. As an example, a first transportation path can start in and/or extend through the first area 512 and can further extend through the deposition area 515 and optionally through the second area 518. The one or more transportation paths, such as the first transportation path, can provide or be defined by, a transport direction 3 of the substrates past the one or more sputter deposition sources.

The substrates 10 can be positioned on respective substrate supports or carriers, such as E-chucks. The substrate support 20 can be configured for transportation along the one or more transportation paths or transportation tracks extending in the transport direction 3. Each substrate support 20 is configured to support a substrate 10, for example, during a vacuum deposition process or layer deposition process, such as a sputtering process or a dynamic sputtering process. The substrate support 20 can include a plate or a frame configured for supporting the substrate 10, for example, using a support surface provided by the plate or frame. Optionally, the substrate support 20 can include one or more holding devices (not shown) configured for holding the substrate 10 at the plate or frame. The one or more holding devices can include at least one of mechanical, electrostatic, electrodynamic (van der Waals), and electromagnetic devices. As an example, the one or more holding devices can be mechanical and/or magnetic clamps. In some implementations, the substrate support 20 is an E-chuck.

According to some embodiments, which can be combined with other embodiments described therein, the substrate 10 is in a substantially vertical orientation, for example, during the vacuum deposition process and/or during transportation of the substrate 10 through the vacuum chamber 510. As used throughout the present disclosure, “substantially vertical” is understood particularly when referring to the substrate orientation, to allow for a deviation from the vertical direction or orientation of +20° or below, e.g. of ±10° or below. This deviation can be provided for example because a substrate support or carrier with some deviation from the vertical orientation might result in a more stable substrate position or a facing down substrate orientation might even better reduce particles on the substrate during deposition. Yet, the substrate orientation, e.g., during a layer deposition process, is considered substantially vertical, which is considered different from the horizontal substrate orientation, which may be considered as horizontal ±20° or below.

Specifically, as used throughout the present disclosure terms like “vertical direction” or “vertical orientation” are understood to distinguish over “horizontal direction” or “horizontal orientation”. The vertical direction can be substantially parallel to the force of gravity.

According to some embodiments, which can be combined with other embodiments described herein, the system 500 is configured for dynamic sputter deposition on the substrate(s). A dynamic sputter deposition process can be understood as a sputter deposition process in which the substrate 10 is moved through the deposition area 515 along the transport direction 3 while the sputter deposition process is conducted. In other words, the substrate 10 is not stationary during the sputter deposition process.

In some implementations, the system 500 is configured for dynamic processing. The system 500 can particularly be an in-line processing system, i.e., a system for dynamic deposition, particularly for dynamic vertical deposition, such as sputtering. An in-line processing system or a dynamic deposition system according to embodiments described herein provides for a uniform processing of the substrate 10, for example, a large area substrate such as a rectangular glass plate. The processing tools, such as the one or more sputter deposition sources, extend mainly in one direction (e.g., the vertical direction) and the substrate 10 is moved in a second, different direction (e.g., a transport direction 3, which can be a horizontal direction).

Apparatuses or systems for dynamic vacuum deposition, such as in-line processing apparatuses or systems, have the advantage that processing uniformity, for example, layer uniformity, in one direction is only limited by the ability to move the substrate 10 at a constant speed and to keep the one or more sputter deposition sources stable. The deposition process of an in-line processing apparatus or a dynamic deposition apparatus is determined by the movement of the substrate 10 past the one or more sputter deposition sources. For an in-line processing apparatus, the deposition area or processing area can be an essentially linear area for processing, for example, a large area rectangular substrate. The deposition area can be an area into which deposition material is ejected from the one or more sputter deposition sources for being deposited on the substrate 10. In contrast thereto, for a stationary processing apparatus, the deposition area or processing area would basically correspond to the area of the substrate 10.

In some implementations, a further difference of an in-line processing system, for example, for dynamic deposition, as compared to a stationary processing system can be formulated by the fact that the dynamic in-line processing system can have one single vacuum chamber with different areas, wherein the vacuum chamber does not include devices for vacuum tight sealing of one area of the vacuum chamber with respect to another area of the vacuum chamber. Contrary thereto, a stationary processing system may have a first vacuum chamber and a second vacuum chamber which can be vacuum tight sealed with respect to each other using, for example, valves.

According to some embodiments, which can be combined with other embodiments described herein, the system 500 includes a magnetic levitation system for holding the substrate support 20 in a suspended state. Optionally, the system 500 can use a magnetic drive system configured for moving or conveying the substrate support 20 within the vacuum chamber 510, for example, in the transport direction 3. The magnetic drive system can be included in the magnetic levitation system or can be provided as a separate entity.

According to some embodiments, which can be combined with other embodiments described herein, the system 500 can be configured as a dual-line system. As an example, the vacuum processing module can include two in-line units, such as a first (upper) in-line unit and a second (lower) in-line unit, for vacuum deposition. The first in-line unit 501 and the second in-line unit 502 can be combined in a mirrored manner. The first in-line unit 501 and the second in-line unit 502 can both be provided in the same vacuum chamber, such as the vacuum chamber 510. The first in-line unit 501 and the second in-line unit 502 share common sputter deposition sources, which can be bi-directional sputter deposition sources. The common sputter deposition sources for a simultaneous deposition of material onto substrates allow for a higher throughput. The simultaneous processing using two in-line units within one vacuum chamber 510 of the system 500 reduces a footprint of the system 500. Particularly for large area substrates, the footprint can be a relevant factor for reducing the cost of ownership for the system 500.

Each in-line unit, such as the first (upper) in-line unit and the second (lower) in-line unit, includes a first area 512, a deposition area 515, and optionally a second area 518. The first areas extend parallel to each other and the deposition areas extend parallel to each other, wherein the one or more sputter deposition sources are provided between the deposition areas. The second areas can extend parallel to each other.

According to some embodiments, the system 500 includes the one or more sputter deposition sources, such as one or more first sputter deposition sources 532, one or more second sputter deposition sources 534 and one or more third sputter deposition sources 536. According to some embodiments, which can be combined embodiments described herein, the deposition area(s) can be included in a scalable chamber section 514. As an example, the vacuum chamber 510 can be manufactured or constructed from at least three sections. The at least three sections can be connected to each other to form the vacuum chamber 510. The first section of the at least three sections provides the first area(s). The second section of the at least three sections provides the scalable chamber section 514 and the deposition area(s), and the third section of the at least three sections provides the second area(s).

The scalable chamber section 514 provides the processing tools, for example, the one or more sputter deposition sources. The scalable chamber section 514 can be provided in various sizes in order to allow for a varying amount of processing tools to be provided in the scalable chamber section 514. As an example, the vacuum chamber 510 is configured to accommodate variable numbers of sputter deposition sources.

The deposition area 515 can have two or more deposition sub-areas each having one or more sputter deposition sources. Each deposition sub-area can be configured for layer deposition of a respective material. The sputter deposition sources in at least some of the deposition sub-areas can be different. FIG. 5 shows the scalable chamber section 514 with five sputter deposition sources. The first sputter deposition source (previously referred to as “one or more first sputter deposition sources 532”) can provide a first material. The second, the third, and the fourth sputter deposition source (previously referred to as “one or more second sputter deposition sources 534”) can provide a second material. The fifth sputter deposition source (previously referred to as “one or more third sputter deposition sources 536”) can provide a third material. For example, the third material can be the same material as the first material. Accordingly, a three layer stack can be provided on the substrate 10, such as a large area substrate. For example, the first and the third material can be molybdenum and the second material can be aluminum.

According to some embodiments, which can be combined with other embodiments described herein, the number of sputter deposition sources or cathodes per material and/or the power provided to the individual sputter deposition sources or cathodes can be varied to tune the target thickness relation between the respective layers. As an example, a number of the sputter deposition sources is selected according to a thickness of a material layer that is to be deposited on a substrate passing the sputter deposition sources. Accordingly, the number of cathodes and the power to the individual cathodes can be used as tuneable variables to achieve a predetermined thickness of each layer at the same passing speed of the substrate moving past the cathodes. As an example, when different material layers are to be deposited on the substrate (for example, the sputter deposition sources could include the above-mentioned aluminum cathodes and molybdenum cathodes to sputter at least two different material layers), a thickness of the deposited layers can be controlled by adjusting or scaling a number of cathodes in the deposition area or respective deposition sub-area and/or by varying the amount of power supplied to the individual cathodes of different materials.

The two or more deposition sub-areas can be separated from each other using gas separation units 538 (also referred to as “gas separation shielding”). As an example, between the sputter deposition sources for providing different materials on the substrate, gas separation units 538 can be provided. The gas separation units 538 can provide for separating a first processing area in the deposition area 515 from a second processing area in the deposition area 515, wherein the first processing area has a different environment, for example, different processing gases and/or a different pressure, as compared to the second processing area. The gas separation units 538 can have an opening configured for allowing a passage of the substrate through the opening.

In some implementations, the deposition area 515 includes a partition 517 provided in a chamber region between the one or more sputter deposition sources and a chamber wall of the vacuum chamber 510. As an example, a first partition is provided in a chamber region between the one or more sputter deposition sources and a first chamber wall of the first in-line unit 501. A second partition can be provided in a chamber region between the one or more sputter deposition sources and a second chamber wall of the second in-line unit 502. According to some embodiments, the partition 517, such as the first partition and the second partition, can be separation walls, such as vertical walls. As an example, the partition 517 can extend substantially parallel to the chamber wall and/or a respective transport direction, such as the transport direction 3.

The partition 517 of an in-line unit separates the chamber region into the respective deposition area and a respective transportation area, wherein the transportation area 516 is at least partially shielded from the one or more sputter deposition sources. The system 500 can be configured for substrate transportation along the first transportation path through the deposition area 515 of a respective in-line unit and along a second transportation path through the transportation area 516 of a respective in-line unit. In particular, the first transportation path can be a forward transportation path. The second transportation path can be a return transportation path.

The first area 512 and the second area 518 can be track switch areas (first area 512: track switching load/unload; second area 518: track switching return) configured for moving the substrate or substrate carrier from the first transportation path to the second transportation path and/or vice versa. The first area 512 and the second area 518 are sufficiently long enough to allow for the track switch. The track switch areas can be at each end of the dynamic-deposition zone. This allows for a continuous substrate flow (dynamic deposition) without the need for “run up” and “run away” chamber sections. The in-line processing system has a smaller footprint.

The first in-line unit 501 may include a first track switching and/or load-unload area in the first area 512 and the second in-line unit 502 may include a second track switching and/or load-unload area in the first area 512. The first track switching and/or load-unload area and the second track switching and/or load-unload area can be separated from each other by a first separation 513. The track switching and/or load-unload areas provide for a substrate movement transverse to the transport direction 3 past the sputter deposition sources. The two track switching and/or load-unload areas can be utilized simultaneously in order to improve the throughput of the system 500.

Within the track switching and/or load-unload area, the substrate support 20 with the substrate 10 is moved on a path for processing the substrate 10, such as the first transportation path. Thereafter, one substrate after the other is moved past the processing tools, for example, the sputter deposition sources. Accordingly, the substrates are processed in the deposition area 515 of the vacuum chamber, for example, the scalable chamber section 514.

The second area 518 provides a track switching return area, such as a first track switching return area of the first in-line unit 501 and a second track switching return area of the second in-line unit 502. The first track switching return area and the second track switching return area can be separated by a second separation 519. The track switching return areas provide for a movement transverse to the transport direction 3 past the sputter deposition sources. Accordingly, a substrate support 20 with the substrate 10 can return to the first area 512 and optionally to the load lock chamber with a distance to the sputter deposition sources that is different (i.e., larger) from the distance to the sputter deposition sources during processing.

FIG. 6B shows a schematic top view of the load lock chambers of FIG. 6A in the enclosure 550 according to embodiments described herein.

The Bernoulli-type holder 110 of the apparatus 100 can include the one or more safety retainers 160. The one or more safety retainers 160 can be moved, for example, rotated, below the substrate 10 as in the lower section of FIG. 6B. In particular, the one or more safety retainers 160 are shown rotated by about 90° just before a pick/place action of the substrate 10 on the door 522 (as indicated with arrow 5). The one or more safety retainers 160 as shown in FIG. 6B would be below the substrate 10 as shown in FIG. 1C and are illustrated above the substrate 10 in FIG. 6B for better understanding.

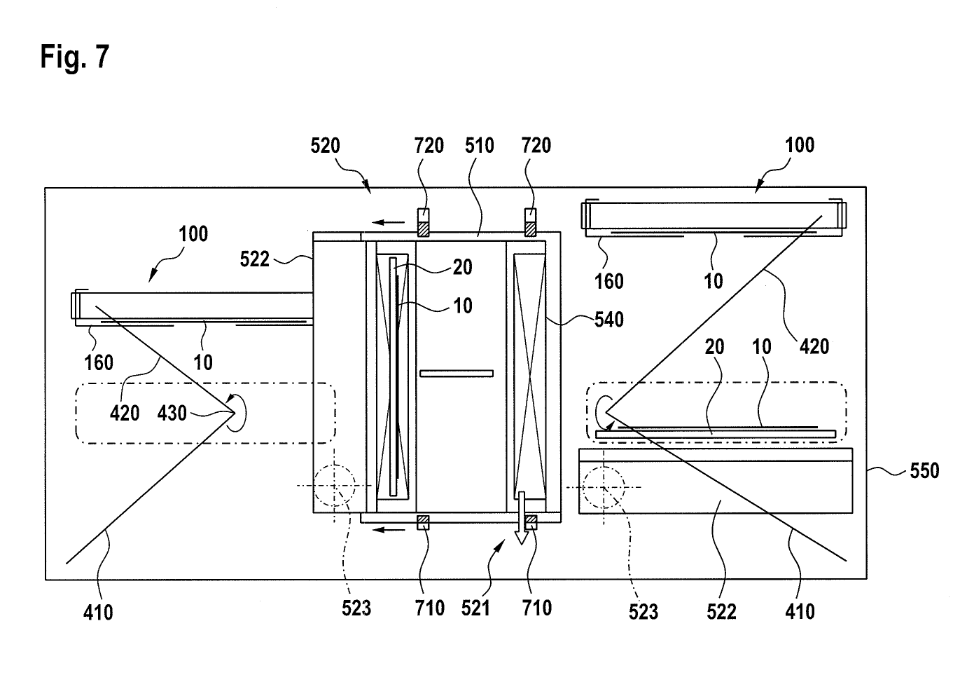

FIG. 7 shows a schematic side view of the load lock chambers of FIG. 6A in the enclosure 550 according to embodiments described herein.

The apparatus 100 can include the two or more rigid ducts, such as the first rigid duct 410 and the second rigid duct 420 connected to each other with a rotary joint 430. The Bernoulli-type holder of the apparatus 100 can be configured to move substantially vertically. As an example, the Bernoulli-type holder can move downwards to put the substrate 10 on a substrate support 20 on the door 522 and/or can move upwards for picking up a substrate 10 from the substrate support 20 on the door 522. The rotary joint 430 allows for a relative movement between the first rigid duct 410 and the second rigid duct 420 such that the Bernoulli-type holder can move, for example, substantially vertically.

According to embodiments described herein, which can be combined with other embodiments described herein, the substrate carriers or substrate supports are supported within the vacuum processing system with a magnetic levitation system. The magnetic levitation system includes first magnets 720 which support the substrate carrier or substrate support 20 in a hanging position without mechanical contact. The magnetic levitation system provides a levitation, i.e. contactless support, of the substrate carriers. Accordingly, particle generation due to movement of the substrate carriers within the system for dynamic deposition can be reduced or avoided. That magnetic levitation system includes the first magnets 720, which provide a force to the top of the substrate carrier, which is substantially equal to the gravity force. That is, the substrate carriers are hanging contactless below the first magnets 720.

Further, the magnetic levitation system can include second magnets 710, which provide for a translational movement along a transportation direction of the substrate carriers. The substrate support 20 can be contactlessly supported within the load lock chamber and/or the vacuum processing system by the first magnets 720 and moved within the load lock chamber and/or the vacuum processing system using the second magnets 710.

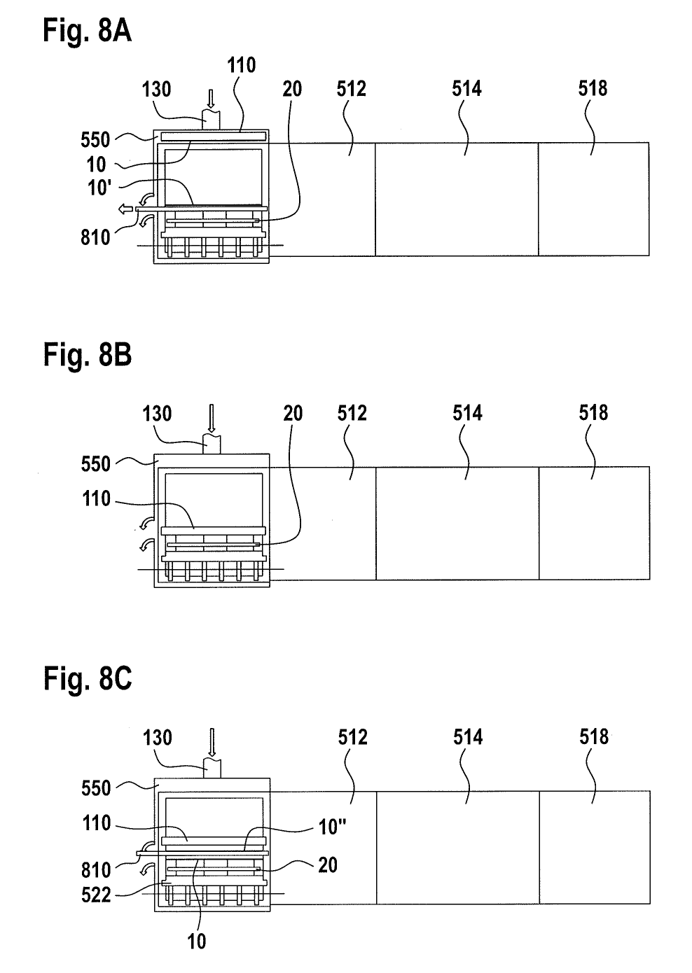

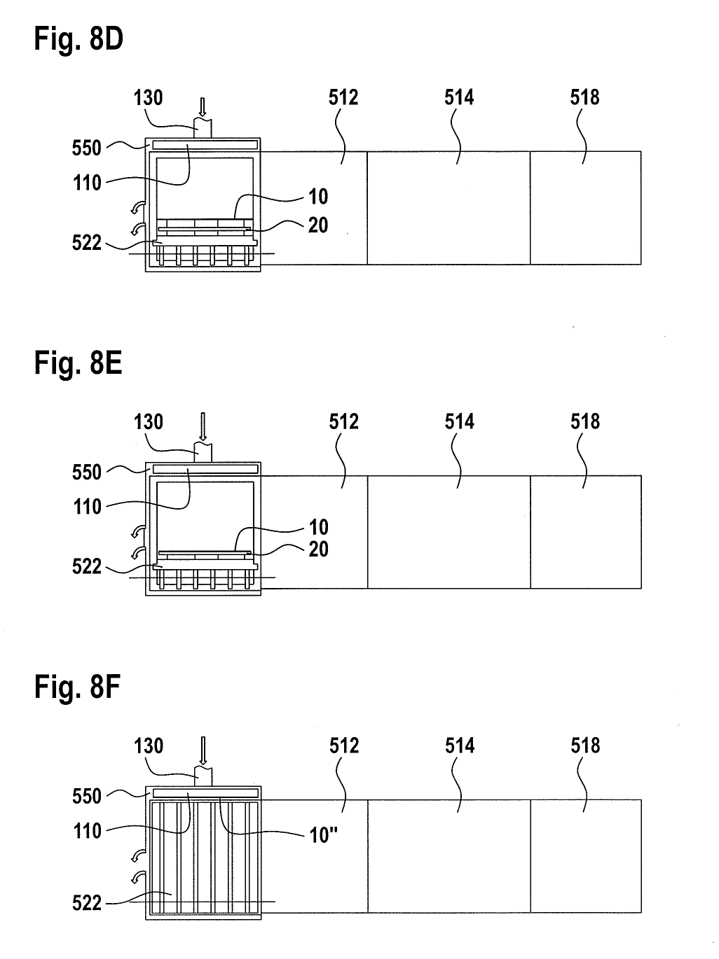

FIGS. 8A-F show schematic views of a loading procedure of a substrate 10 into a load lock chamber of the system 500 of FIG. 6A using the Bernoulli-type holder 110 of the apparatus according to the embodiments described herein. The load lock chamber of the present disclosure can be a combined swing module and load lock chamber.

The Bernoulli-type holder 110 can be used for loading the substrate 10, such as a large area substrate, on a substrate support surface and/or for unloading the large area substrate from the substrate support surface. The substrate support surface can be provided by the door 522 of the load lock chamber, or can be provided by a substrate support 20, such as an E-chuck, positioned on the door 522. As an example, the substrate support surface may be the substrate carrier to be used to hold and transport the substrate through the vacuum processing system. In particular, the substrate support 20 may be an electrostatic chuck or may have an electrostatic chuck attached to a surface of the substrate support 20, which can be used to hold the substrate to the substrate support 20. The Bernoulli-type holder 110 can be used for putting the substrate 10 on the door 522, wherein the door 522 is then rotated around a rotational axis 523, e.g., a horizontal rotational axis, from a first orientation (e.g., a horizontal orientation) to a second orientation (e.g., a vertical orientation) to load the substrate 10 into the load lock chamber. In particular, the rotation of the door 522 can move the substrate 10 and/or the substrate support 20 from a horizontal orientation into a vertical orientation. In some implementations, the Bernoulli-type holder 110 is arranged over the door 522 of the load lock chamber in the open position of the door 522.

A method of loading and/or unloading a substrate 10 in a dynamic deposition system can include at least a loading and holding of a substrate 10 in a Bernoulli-type holder 110, a treating or pre-treating of the substrate 10 in the Bernoulli-type holder 110 according to the embodiments described herein, and a loading of the substrate 10 at the load lock chamber after the treating, for example, onto the door 522 or the substrate support 20 positioned on the door 522.

The loading and/or unloading in a substrate exchange sequence can use the Bernoulli-type holder 110. This allows substrates to be loaded into/unloaded from the system by a single factory automation robot at the rate of, for example, 60sph while providing for pre-heating/degassing of each substrate before processing.

In some implementations, the Bernoulli-type holder 110 can be moved in a wait position for conducting the treatment of the substrate. As an example, the wait position is above the door 522, which is configured as a rotatable support.

In FIG. 8A, a robot 810 such as an FE or a front end robot, removes a coated substrate 10′, e.g. from lift pins shown above the substrate support 20. The Bernoulli-type holder 110 supports another substrate 10, which is preconditioned. The substrate 10 is preconditioned with the Bernoulli-type holder 110 being in a waiting position, for example, above the door 522. For example, the substrate 10 is heated by utilizing the Bernoulli-type holder 110 with heated gas. Additionally or alternatively, the substrate 10 can be cleaned by utilizing the Bernoulli-type holder 110 with a clean, dry and chemically inert gas, for example nitrogen. The substrate 10 is pre-treated (heated and/or cleaned etc.) in the enclosure 550 for a waiting time while other loading and/or unloading procedures take place, for example the removing of the coated substrate 10′ with robot 810 shown in FIG. 8A.

The pre-treated, for example pre-heated, substrate 10, which is shown in the Bernoulli-type holder 110 in FIG. 8A, is moved on the substrate support 20, for example, by lowering the Bernoulli-type holder 110. In the example shown in FIG. 8B, the substrate 10 is provided on the lift pins above the substrate support 20.

In order to move the Bernoulli-type holder 110, the gas supply 130 for the Bernoulli-type holder 110 can be moved as well. According to some embodiments, which can be combined with other embodiments described herein, the gas, for example nitrogen, provided to the Bernoulli-type holder 110 is provided through the two or more rigid ducts. The two or more rigid ducts can be heated. Further, the two or more rigid ducts can be connected to each other to provide a fluid communication with a rotary joint. The two or more rigid ducts reduce particle generation as compared to other flexible gas supply conduits.

In FIG. 8C, the pre-treated substrate 10 has been located on the lift pins and the robot 810 moves a new, fresh substrate 10″ into the enclosure 550, which is picked up by the Bernoulli-type holder 110. The Bernoulli-type holder 110 supports the fresh substrate 10″ (on the gas cushion, i.e. contactlessly) and moves upward to the waiting position shown in FIG. 8D, in which the fresh substrate 10″ is pre-treated, for example heated, while other loading and/or unloading procedures take place.

In FIG. 8E, the pre-treated substrate 10 is lowered on the substrate support 20. This can for example be provided by retracting the lift pins such that the substrate 10 is placed on the substrate support 20. The substrate 10 can be aligned and/or can be electronically chucked to the substrate support 20, which can be an E-chuck.

As shown in FIG. 8F, the door 522 of the load lock chamber closes with a rotational movement. By closing the door 522 of the load lock chamber, the substrate 10, which is fixed on the substrate support 20, is moved from a first orientation, for example essentially horizontally, to a second orientation, for example essentially vertically, to be processed in the second orientation. The movement includes a rotation around the rotational axis 523, which can be substantially horizontal.

The Bernoulli-type holder 110 or heater provides a device for pre-heating and degassing a substrate, particularly of adsorbed water, before the substrate enters a vacuum system. The substrates can be pre-treated, for example pre-heated, while the Bernoulli-type holder 110 is in the waiting position, see for example FIGS. 8D, 8E, and 8F. The Bernoulli-type holder 110 provides a well-controlled, clean, dry, chemically-inert environment for the surface of the substrate that is to be processed, for example, on which a layer is to be coated. As shown in FIGS. 8A to 8F, this can be provided while the substrate is degassing and waiting to be processed.

According to yet further embodiments, which can be combined with other embodiments described herein, the Bernoulli-type holder 110 is configured for transporting and picking/placing the substrate directly from/onto another device, without any specific devices or locations of support such as lift pins. Even though lift pins are shown in FIGS. 8A to 8F, lift pins to be arrayed on the backside of the substrate may not be provided when utilizing the Bernoulli-type holder 110.

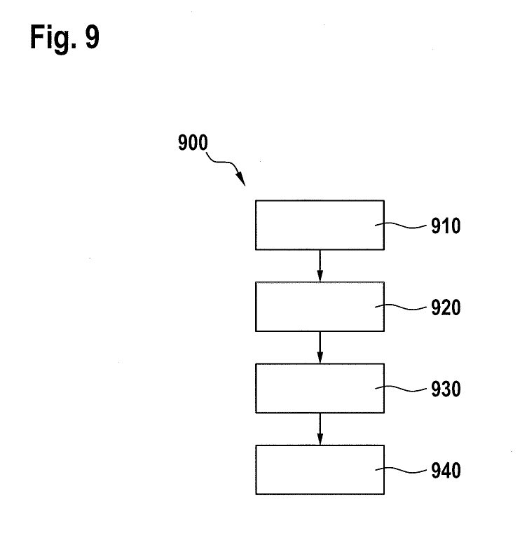

FIG. 9 shows a flow chart of a method 900 according to embodiments described herein, such as the method for loading a large area substrate into a vacuum processing module or the method for treatment of a substrate for a vacuum deposition process in a vacuum processing module. The method 900 can utilize the apparatuses and systems according to the embodiments described herein.

A method 900 for loading a large area substrate into a vacuum processing module according to the embodiments described therein can include a holding of the substrate with a Bernoulli-type holder (block 910), and a loading of the substrate onto a substrate carrier provided at a load lock chamber connected to the vacuum processing module using the Bernoulli-type holder (block 920). The substrate can be a large area substrate.

According to some embodiments, the method 900 further includes loading the substrate carrier having the substrate positioned thereon into the load lock chamber. As an example, the substrate is loaded onto the substrate carrier before the substrate carrier having the substrate positioned thereon is loaded into the load lock chamber. In further embodiments, the substrate is loaded onto the substrate carrier already inside the load lock chamber. The substrate carrier can be an E-chuck, which may be fixed to a support surface provided by the load lock chamber, such as the rotatable door described with respect to FIG. 6A.

In some implementations, the method 900 further includes a guiding of a stream of gas via a gas supply of the Bernoulli-type holder along a surface of the substrate while holding the substrate with the Bernoulli-type holder (block 930), and a treating of the substrate with the stream of gas while guiding the stream of gas, wherein at least one physical and/or chemical property of the gas is selected for the treating of the substrate (block 940).

According to further embodiments of the present disclosure, a method for treatment of a substrate for a vacuum deposition process in a vacuum processing module includes holding the substrate with a substrate holder configured for loading the substrate at a load lock chamber of the vacuum processing module. As an example, the substrate holder is configured for loading the substrate, for example, onto a substrate carrier, at a loading station or position of the load lock chamber. The method further includes a guiding of a stream of gas via a gas supply along a surface of the substrate while holding the substrate with the substrate holder, a treating of the substrate with the stream of gas while guiding the stream of gas, and a loading of the substrate into or onto the load lock chamber with the substrate holder. At least one physical and/or chemical property of the gas is selected for the treating of the substrate.

According to some embodiments, the method further includes loading the substrate carrier having the substrate positioned thereon into the load lock chamber. As an example, after the treatment, the substrate is loaded onto the substrate carrier before the substrate carrier having the substrate positioned thereon is loaded into the load lock chamber. In further embodiments, the substrate is loaded onto the substrate carrier already inside the load lock chamber.

According to some embodiments, the treatment of the substrate comprises at least one of heating the substrate and degassing the substrate. The treatment can further include providing at least one of a clean, dry, and chemically-inert environment at least for the surface of the substrate.

In some implementations, the holding of the substrate includes a generation of a pressure, such as a reduced pressure or under pressure, above the surface of the substrate for levitation of the substrate. In particular, the substrate holder can be the Bernoulli-type holder as described herein.

According to embodiments described herein, the method for loading a substrate into a vacuum processing module and the method for treatment of a substrate for a vacuum deposition process in a vacuum processing module can be conducted using computer programs, software, computer software products and the interrelated controllers, which can have a CPU, a memory, a user interface, and input and output devices being in communication with the corresponding components of the systems and apparatuses according to the embodiments described herein.

The present disclosure provides at least some of the following aspects and advantages. The embodiments of the present disclosure direct a stream of gas across at least one surface of a substrate, such as a large area substrate, in a controlled manner. The stream of gas can be used for at least one of treating the substrate, for example, before the substrate is loaded into a vacuum processing module, and holding the substrate in a levitating state. In particular, the stream of gas can be used for an outgassing of the substrate and/or for a removal of foreign particles from the surface of the substrate on which a material layer is to be deposited. As an example, an outgassing of the substrate can be performed using the stream of gas before the substrate is put on a substrate carrier, such as an E-chuck. A quality, such as a purity and/or a homogeneity, of the deposited layers can be improved. Further, the stream of gas can be used to generate a pressure above the substrate such that the substrate levitates. In particular, the stream of gas can simultaneously provide two functions, namely a holding function and a treatment or pre-treatment function for the substrate.

While the foregoing is directed to embodiments of the disclosure, other and further embodiments of the disclosure may be devised without departing from the basic scope thereof, and the scope thereof is determined by the claims that follow.

1. Apparatus for loading a substrate into a vacuum processing module, comprising:
a Bernoulli-type holder having a surface configured to face the substrate; and
a gas supply configured to direct a stream of a gas between the surface and the substrate, wherein the Bernoulli-type holder is configured to provide a pressure between the substrate and the surface configured for levitation of the substrate, and wherein the substrate is a large area substrate.

2. The apparatus of claim 1, further including at least one of: one or more conditioning devices for adjusting at least one physical and chemical property of the gas directed between the surface and the substrate, wherein at least one of: the physical and/or chemical property of the gas is selected for a treatment of the substrate.

3-4. (canceled)

5. The apparatus of claim 2, wherein the one or more conditioning devices are selected from the group consisting of a heater configured for heating the gas, a dryer configured for drying the gas, a filter for filtering the gas, a compressor, and any combination thereof.

6. The apparatus of claim 2, wherein the Bernoulli-type holder further includes one or more safety retainers configured to be positioned below the substrate, wherein a gap is provided between the substrate and the safety retainer.

7. The apparatus of claim 6, wherein the one or more safety retainers are configured to be rotatable with respect to the substrate.

8. The apparatus of claim 1, wherein the gas supply includes two or more rigid ducts, and wherein at least a first rigid duct and a second rigid duct of the two or more rigid ducts are connected to each other with a rotary joint to allow for fluid communication between the first rigid duct and the second rigid duct.

9. The apparatus of claim 1, further including one or more substrate alignment devices.

10. The apparatus of claim 9, wherein the one or more substrate alignment devices include at least one of one or more moveable substrate alignment devices and one or more fixed substrate alignment devices.

11. System for vacuum processing of a substrate, comprising:
a processing module configured for a vacuum deposition process on the substrate;
at least one load lock connected to the processing module; and
an apparatus for loading a substrate into a vacuum processing module, the apparatus comprising:
a Bernoulli-type holder having a surface configured to face the substrate; and
a gas supply configured to direct a stream of a gas between the surface and the substrate, wherein the Bernoulli-type holder is configured to provide a pressure between the substrate and the surface configured for levitation of the substrate, and wherein the substrate is a large area substrate.

12. Method for loading a substrate into a vacuum processing module, comprising:
holding the substrate with a Bernoulli-type holder, wherein the substrate is a large area substrate; and
loading the substrate onto a substrate carrier provided at a load lock chamber connected to the vacuum processing module using the Bernoulli-type holder.

13. The method of claim 12, further comprising:
loading the substrate carrier having the substrate positioned thereon into the load lock chamber.

14. The method of claim 12, further comprising:
guiding a stream of gas via a gas supply of the Bernoulli-type holder along a surface of the substrate while holding the substrate with the Bernoulli-type holder; and
treating the large area substrate with the stream of gas while guiding the stream of gas, wherein at least one property of the gas is selected for the treating of the substrate.

15. Method for treatment of a substrate for a vacuum deposition process in a vacuum processing module, comprising:
holding the substrate with a substrate holder configured for loading the substrate at a load lock chamber of the vacuum processing module;
guiding a stream of a gas via a gas supply along a surface of the substrate while holding the substrate with the substrate holder;
treating the substrate with the stream of gas while guiding the stream of gas, wherein at least one physical or chemical property of the gas is selected for the treating of the substrate; and
loading the substrate onto a substrate carrier provided at the load lock chamber with the substrate holder.

16. The method of claim 14, wherein the treating of the substrate includes at least one of a heating of the substrate and a degassing of the substrate.

17. The method of claim 14, wherein the treatment of the substrate further includes providing at least one of a clean, dry, and chemically-inert environment at least for a surface of the substrate.

18. The method of claim 12, wherein the holding of the substrate includes a generation of a pressure above a surface of the substrate for levitation of the substrate.

19. The apparatus of claim 4, wherein the area of the surface of the Bernoulli-type holder is greater than an area of the substrate surface facing the surface of the Bernoulli-type holder.

20. The method of claim 13, further comprising:
guiding a stream of gas via a gas supply of the Bernoulli-type holder along a surface of the substrate while holding the substrate with the Bernoulli-type holder; and
treating the large area substrate with the stream of gas while guiding the stream of gas, wherein at least one property of the gas is selected for the treating of the substrate.

21. Apparatus configured for treatment of a substrate for a vacuum deposition process in a vacuum processing module, comprising:
a substrate holder configured to hold the substrate;
a gas supply configured to direct a stream of a gas along a substrate surface of the substrate; and
one or more conditioning devices for adjusting at least one physical and chemical property of the gas directed along the substrate surface, wherein the at least one of physical and chemical property of the gas is selected for a treatment of the substrate.

22. The apparatus of claim 21, wherein the substrate holder is a Bernoulli-type holder having a surface configured to face the substrate, and wherein the gas supply is configured to direct a stream of gas between the surface and the substrate for levitation of the substrate.
